(19) United States
(12) Patent Application Publication
(10) Pub. No.: US 2010/0074289 A1
(43) Pub. Date: Mar. 25, 2010

(54) SEMICONDUCTOR LIGHT EMITTING ELEMENT

(75) Inventors: Ryuji Kobayashi, Tokyo (JP); Shigeo Sugou, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 11/993,614

(22) PCT Filed: Sep. 8, 2006
(86) PCT No.: PCT/JP2006/317837

§ 371 Date: Dec. 21, 2007

(30) Foreign Application Priority Data
Sep. 15, 2005 (JP) 2005-268691

(51) Int. Cl. H01S 5/40; H01S 5/343

(52) U.S. Cl. 372/45.01

(57) ABSTRACT

A two-wavelength semiconductor laser 1 includes an n-type GaN substrate 101, an n-type GaAs substrate 201 disposed on a predetermined face of the n-type GaN substrate 101, a blue-violet laser 100 provided on one of faces of the n-type GaN substrate 101 and including a multi-quantum well active layer 105, and a red laser 200 provided on one of faces of the n-type GaAs substrate 201 and including a multi-quantum well active layer 205. The blue-violet laser 100 and the red laser 200 emit laser beams having wavelengths different from each other. The blue-violet laser 100 and the red laser 200 are disposed so that their cavity length directions are almost parallel with each other. The cavity length of the blue-violet laser 100 is shorter than that of the red laser 200.

### TECHNICAL FIELD

The present invention relates to a semiconductor light emitting element and, more particularly, to an integrated semiconductor laser device in which a plurality of semiconductor light emitting elements are integrated.

### BACKGROUND ART

It is considered that a two-wavelength or three-wavelength semiconductor laser in which a 400-nm band GaN (gallium nitride)-based blue-violet laser and a 650-nm AlGaInP (aluminum gallium indium phosphor)-based red laser or 780-nm AlGaAs (aluminum gallium arsenic)-based infrared laser are integrated will be the mainstream as a light source for a high-density optical disc of the next generation such as an HD-DVD or Blue-ray disc for the reason that, by using it, the number of parts can be reduced and downsizing and lower cost of an optical pickup can be realized.

Such a multiwavelength laser is described in a patent document 1. The patent document 1 describes a two-wavelength laser in which a laser element that emits light at a wavelength of 650 nm and a laser element that emits light at a wavelength of 780 nm are joined by their anode-side electrodes. It is disclosed that with the configuration, light emission points can be arranged close to each other. According to the document the device configuration is simplified so that miniaturization thereof can be achieved.

With respect to each of lasers constructing a multiwavelength laser, an AlGaInp-based red laser realizes a high output power by increasing the cavity length to improve the radiation performance since the thermal conductivity of the laser is low. As a result, as described in a non-patent document 1, in a pulse-operation 240 mW laser used for 16× write, the cavity length is considerably as long as 1,500 ƒÊm. In a high output power laser adapted to writing to a two-layer disk, it is considered that the cavity length is further increased for a higher light output.

On the other hand, the GaN-based blue-violet laser can realize a high output power with a relatively short cavity length because of its high thermal conductivity. For example, a high output power characteristic of a GaN-based blue-violet laser of 200 mW (CW (continuous wave) operation) with a cavity length of 600 ƒÊm is reported in a non-patent document 2.
[Patent Document 1] Japanese Laid-open patent publication No. 11-112091
[Patent Document 2] Japanese Laid-open patent publication No. 61-280693
[Non-Patent Document 1] Shinichi Agatsuma and seven others, “Monolithic Dual-Wavelength Lasers for CD-R/DVD±RW/R/RW”, 19th IEEE International Semiconductor Laser Conference, September 2004, Conference Digest, pp. 123-124
[Non-Patent Document 2] Masao Ikeda and seven others, “High-power GaN-based semiconductor lasers” physica Status Solidi (c), 2004, Vol. 1, No. 6, pp. 1461-1467
[Non-Patent Document 3] Shiro Uchida and eight others, “Recent Prgress in High-Power Blue-Violet Lasers”, IEEE Journal of Selected Topics in Quantum Electronics, 2003, Vol. 9, No. 5, pp. 1252-1259
[Non-Patent Document 4] Tetsuya Yagi and seven others, “High-Power High-Efficiency 660-nm Laser Diodes for DVD-R/RW”, IEEE Journal of Selected Topics in Quantum Electronics, 2003, Vol. 9, No. 5, pp. 1260-1264

### DISCLOSURE OF THE INVENTION

In the two-wavelength or three-wavelength semiconductor laser, taking the above-described characteristics of the lasers into account, a configuration of integrating a high-output power AlGaInP-based red laser and a high-output power AlGaAs-based infrared laser on a GaN-based blue-violet laser as a heat sink is considered. In the case of fabricating such a two-wavelength or three-wavelength laser, to assure the radiation performance, the length in the cavity length direction of the substrate of the GaN-based blue-violet laser has to be assured in accordance with the cavity lengths of the AlGaInP-based red laser and the AlGaAs-based infrared laser. Accordingly, the cavity length of the GaN-based blue-violet laser becomes long. For example, in the case of integrating a 16× write AlGaInP-based red laser (having a cavity length of 1,500 ƒÊm, for example) and a 32× write AlGaAs-based infrared laser (having a cavity length of 900 ƒÊm, for example), the GaN-based blue-violet laser has a cavity length of 1,500 ƒÊm or longer.

However, an internal loss of the GaN-based blue-violet laser is about 10 to 30 cm⁻¹ which is larger than that of the AlGaInP-based red laser (internal loss of 5 cm⁻¹ or less) (non-patent documents 3 and 4). Thus, there is a concern that the increase in the cavity length of the GaN-based blue-violet laser brings about an increase in drive current due to drop in the slope efficiency, that is, drop in external differential quantum efficiency.

The GaN-based blue-violet laser is fabricated on a GaN substrate having a dislocation density of 10⁵ to 10⁷ cm⁻² or a laterally-grown GaN layer grown on a sapphire substrate. The above-described non-patent document 2 describes that the dislocation in the GaN substrate or the laterally-grown GaN layer relates to the element lifetime.

It is therefore concerned that when the cavity length is increased in the GaN-based blue-violet laser, the number of dislocations included in a waveguide as a light emission unit increases, and the reliability deteriorates. At present, there is no actual report on excellent reliability in an element having a cavity length exceeding 700 ƒÊm.

The present invention has been achieved in view of the circumstances and provides a technique of improving the laser characteristic and reliability in a multiwavelength semiconductor laser in which a plurality of semiconductor lasers are integrated.

According to the present invention, there is provided a semiconductor light emitting element including at least two laser structures that emit laser beams having wavelengths different from each other, including: a first substrate; a second substrate disposed on a predetermined face of the first substrate; a first laser structure provided on one of faces of the first substrate and including a first active layer; and a second laser structure provided on one of faces of the second substrate and including a second active layer. The first and second laser structures are disposed so that their cavity length directions are almost parallel with each other, and the cavity length of the first laser structure is shorter than that of the second laser structure.

In the present invention, the laser structure refers to a laminated body constructed by clad layers and layers sandwiched by the clad layers, and includes an active layer. According to the invention, the second substrate is disposed on one of faces of the first substrate. Consequently, by using the first substrate as a heat sink, the radiation performance of the second laser structure can be improved. The cavity length of the first laser structure is shorter than that of the second laser structure. Thus, in the case where the size of the first substrate is assured to a degree that the radiation performance of the second laser structure can be sufficiently assured, deterioration in the laser characteristic and reliability accompanying increase in the cavity length of the first laser structure can also be suppressed. Therefore, in the construction including the first and second laser structures of wavelengths different from each other, the laser characteristic and reliability can be improved.

In the semiconductor light emitting element of the present invention, when the cavitylength of the first laser structure is L1, the cavitylength of the second laser structure is L2, and length in the cavity length direction of the first substrate is L0, L1<L2 may be satisfied and L0 may be equal to or larger than L2. That is, the length in the cavity length direction of the first substrate may be made equal to or larger than the cavity length of the second laser structure integrated on a predetermined face of the first substrate. By employing the configuration that L0 is equal to or larger than L2, the radiation performance of the second laser structure can be further improved. The state where L0 is equal to or larger than L2 denotes a state where the length L0 is assured to a degree that the radiation performance of the second laser structure is sufficiently assured and, for example, L0 is 90% or more of L2.

In the present invention, L0 may be larger than L1 (L0>L1). That is, the length in the cavity length direction of the first substrate may be longer than that of the first laser structure provided on one of the faces of the first substrate. For example, a front facet or a rear facet of the first laser structure is retreated to the inner side of the first substrate compared to the facet of the first substrate. In such a manner, the first substrate can function as a heat sink more effectively, and the cavity length necessary for laser oscillation of the first laser structure is made shorter than the length of the first substrate. Thus, higher efficiency, low drive current, and higher reliability can be assured more sufficiently.

In the semiconductor light emitting element of the present invention, both of the front facet of the first laser structure and the front facet of the second laser structure may be flush with the same facet of the first substrate. With the configuration, while improving the radiation performance of the second laser structure, the semiconductor light emitting element can be miniaturized as a whole.

In the semiconductor light emitting element of the present invention, by removing a part of the first active layer by etching, the front facet or the rear facet of the first laser structure may be formed so as to be retreated to the inner side of the first substrate. In such a manner, manufacturing stability of the front facet or the rear facet of the first laser structure can be improved. With improvement in controllability of the facet position, variations in the cavity length of the first laser structure during manufacture can be suppressed.

In the semiconductor light emitting element of the present invention, the first laser structure may be a GaN-based laser, and the second laser structure may be an AlGaInP-based, AlGaAs-based, GaInAs-based, AlGaInAs-based, InGaAsP-based, InGaAsN-based, or InGaAsNSb-based laser. In the semiconductor light emitting element of the present invention, the first laser structure may be a GaN-based laser including a ridge-shaped upper clad.

The semiconductor laser of the present invention may be, for example, a two-wavelength semiconductor laser in which a blue-violet laser and a red laser are integrated or a three-wavelength semiconductor laser in which a blue-violet laser, a red laser, and an infrared laser are integrated. For example, the two-wavelength semiconductor laser has a configuration in which an AlGaInP-based red laser or AlGaAs-based infrared laser is integrated on a GaN-based blue-violet laser. For example, the three-wavelength semiconductor laser has a configuration in which an AlGaInP-based red laser and an AlGaAs-based infrared laser are integrated on a GaN-based blue-violet laser. According to the present invention, the laser characteristic and reliability of each of the laser structures constructing the multi-wavelength lasers can be improved.

More specifically, by setting the length of the first substrate of the GaN-based blue-violet laser to be equal to or longer than that of the second substrate of the AlGaInP-based red laser or AlGaAs-based infrared laser integrated on the GaN-based blue-violet laser, the radiation performance of the integrated AlGaInP-based red laser or AlGaAs-based infrared laser can be assured. A high output power characteristic equivalent to that of a single body can be realized. On the other hand, in the GaN-based blue-violet laser, by forming a facet by dry etching or the like, the cavity length necessary for laser oscillation is made shorter than the length in the cavity length direction of the second substrate. As a result, a waveguide loss is reduced and the number of dislocations propagating from the substrate to the waveguide stripe is decreased. [symbol] Laser oscillation having high efficiency, low drive current, and high reliability can be realized.

In the semiconductor light emitting element of the present invention, the first substrate may be a substrate of a group-III nitride semiconductor such as a GaN substrate or an AlGaN substrate. With the configuration, the thermal conductivity of the first substrate can be sufficiently assured, and the radiation performance of the second laser structure can be improved.

As described above, the present invention can realize the technique of improving the laser characteristic and reliability of the multi-wavelength semiconductor laser in which a plurality of semiconductor lasers are integrated.

### BRIEF DESCRIPTION OF THE DRAWINGS

FIG. 1 is a bird's-eye view showing a configuration of a two-wavelength semiconductor laser of the present embodiment.

FIG. 2 is a cross-sectional view of the two-wavelength semiconductor laser of FIG. 1.

FIG. 3 is a diagram showing a process of manufacturing a GaN-based blue violet laser in the two-wavelength semiconductor laser of FIG. 1.

FIG. 4 is a diagram showing a process of manufacturing the GaN-based blue violet laser in the two-wavelength semiconductor laser of FIG. 1.

FIG. 5 is a cross-sectional view showing a process of manufacturing an AlGaInP-based red laser in the two-wavelength semiconductor laser of FIG. 1.

FIG. 6 is a cross-sectional view showing a process of manufacturing the AlGaInP-based red laser in the two-wavelength semiconductor laser of FIG. 1.

FIG. 7 is a diagram showing a configuration of a package in which the two-wavelength semiconductor laser of FIG. 1 is assembled.

FIG. 8 is a bird's-eye view showing a configuration of the two-wavelength semiconductor laser of the present embodiment.

FIG. 9 is a bird's-eye view showing a configuration of the two-wavelength semiconductor laser of the present embodiment.

FIG. 10 is a bird's-eye view showing a configuration of the two-wavelength semiconductor laser of the present embodiment.

FIG. 11 is a bird's-eye view showing a configuration of the two-wavelength semiconductor laser of the present embodiment.

FIG. 12 is a bird's-eye view showing a configuration of a GaN-based blue violet laser used for the two-wavelength semiconductor laser of FIG. 11.

FIG. 13 is a bird's-eye view showing a configuration of the two-wavelength semiconductor laser of the present embodiment.

FIG. 14 is a bird's-eye view showing a configuration of a three-wavelength semiconductor laser of the present embodiment.

FIG. 15 is a cross-sectional view of the three-wavelength semiconductor laser of FIG. 14.

FIG. 16 is a bird's-eye view showing a configuration of a GaN-based blue violet laser in the three-wavelength semiconductor laser of FIG. 14. FIG. 17 is a cross-sectional view showing a process of manufacturing an AlGaAs-based infrared laser in the three-wavelength semiconductor laser of FIG. 14.

FIG. 18 is a diagram showing a configuration of a package in which the three-wavelength semiconductor laser of FIG. 14 is assembled.

FIG. 19 is a bird's-eye view showing a configuration of the three-wavelength semiconductor laser of the present embodiment.

FIG. 20 is a cross-sectional view showing a configuration of the three-wavelength semiconductor laser of the present embodiment.

### BEST MODE FOR CARRYING OUT THE INVENTION

An embodiment of the present invention will be described by referring to the drawings with respect to, as an example, the case of integrating, on a substrate of a GaN-based blue violet laser, another laser oscillating a laser beam having a different wavelength. In all of the drawings, the same reference numeral is designated to common components and description will not be repeated below. In the following embodiment, the case where the length of the chip of each of the semiconductor lasers corresponds to the length of the substrate of the semiconductor laser will be described as an example.

### First Embodiment

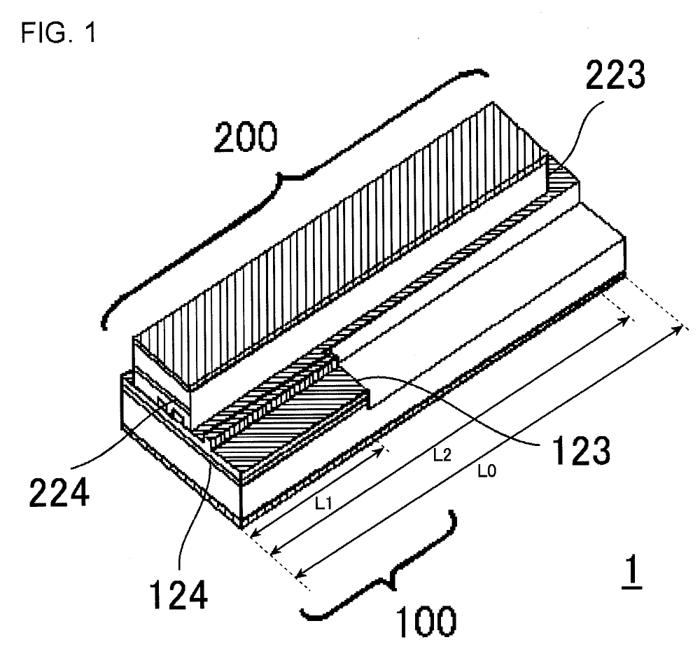

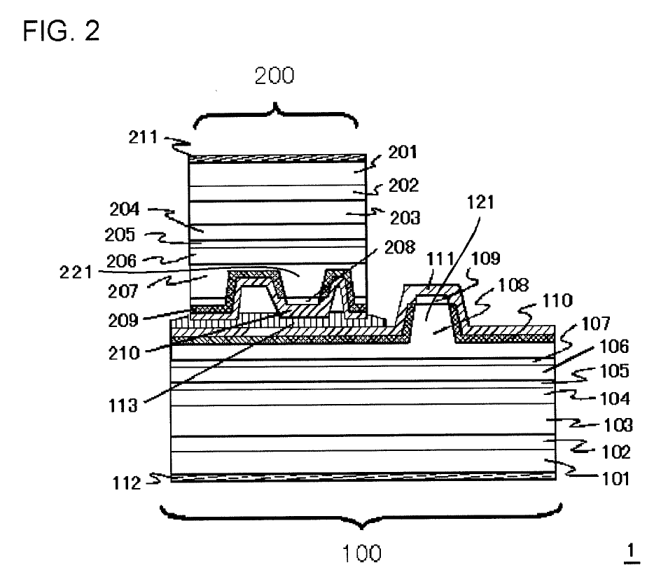

FIG. 1 is a bird's-eye view of a two-wavelength semiconductor laser 1 according to the present embodiment. FIG. 2 is a cross-sectional view of the two-wavelength semiconductor laser 1 shown in FIG. 1 which is cut perpendicular to a cavity direction.

The two-wavelength semiconductor laser 1 is a semiconductor light emitting element including at least two laser structures that oscillate laser beams having different wavelengths.

The two-wavelength semiconductor laser 1 includes a first substrate (n-type GaN substrate 101), a second substrate (n-type GaAs substrate 201) disposed on a predetermined face of the n-type GaN substrate 101, a first laser structure (blue-violet laser 100) which is disposed on one face of the n-type GaN substrate 101 and includes a first active layer (multi-quantum well active layer 105) and a second laser structure (red laser 200) which is disposed on one face of the n-type GaAs substrate 201 and includes a second active layer (multi-quantum well active layer 205). The AlGaInP-based red laser 200 having long cavity length is integrated on the chip of the GaN-based blue-violet laser 100 having short cavity length, that is, on the n-type GaN substrate 101. The multi-quantum well active layers 105 and 205 are provided on the same side with respect to the n-type GaN substrate 101. The red laser 200 is disposed on the side of the blue-violet laser 100.

The blue-violet laser 100 and the red laser 200 are disposed so that their cavity length directions are almost parallel with each other. The cavity length of the blue-violet laser 100 is shorter than that of the red laser 200.

When the cavity length of the blue-violet laser 100 is set as L1, the cavity length of the red laser 200 is set as L2, and the length in the cavity length direction of the n-type GaN substrate 100 is L0, L1 is smaller than L2 (L1<L2), L0 is equal to or larger than L2, and the length of the n-type GaN substrate 101 is assured to a degree that radiation performance of the red laser 200 is sufficiently assured. In the two-wavelength semiconductor laser 1, L0 is larger than L1 (L0>L1).

The thermal conductivity of the blue-violet laser 100 is higher than that of the red laser 200. The thermal conductivity of the laser structure is that of a semiconductor layer formed on the substrate in a laser structure and is, for example, thermal conductivity of a laminated body constructed by clad layers and an active later sandwiched by the clad layers.

The red laser 200 is joined to the n-type GaN substrate 101 via a predetermined layer. For example, the red laser 200 is adhered to the n-type GaN substrate 101 by thermal adhesion, for example. The red laser 200 is fusion-bonded with the p-side down to the p-side of the blue-violet laser 100. When the side of a p-type clad layer 207 (p-type (Al_{0.7}Ga_{0.3})_{0.47}In_{0.53}P layer) having the highest thermal resistance among the layers constructing the red laser 200 is faced to the n-type GaN substrate 101, the radiation performance of the red laser 200 can be further increased. In the red laser 200, the thermal resistance of the p-type clad layer 207 is high. By adhering the entire face of the p-type clad layer 207 to a predetermined face of the n-type GaN substrate 101 via a predetermined layer, the radiation characteristic improves.

Out of the front and rear facets of the blue-violet laser 100, a rear facet 123 is formed by etching. By removing a part of the multi-quantum well active layer 105 by etching, the rear facet 123 of the blue-violet laser 100 is formed so as to be retreated to the inside of the n-type GaN substrate 101 from the facet of the n-type GaN substrate 101, and to the inside of the n-type GaN substrate 101 from a rear facet 223 of the red laser 200.

On the other hand, with respect to the front facet of the laser, a front facet 124 of the blue-violet laser 100 and a front facet 224 of the red laser 200 are flush with the same facet of the n-type GaN substrate 101.

The planar shape of the blue-violet laser 100 is rectangle, and one of the faces of the blue-violet laser 100 has an area where a part of the multi-quantum well active layer 105 is removed by etching. The planar shape of the multi-quantum well active layer 105 is almost an L shape. In the area where the multi-quantum well active layer 105 is not removed, the red laser 200 is disposed on the one of faces of the n-type GaN substrate 101. With the configuration, the area on the n-type GaN substrate 101 from which the multi-quantum well active layer 105 is removed can function as a radiation area, so that the radiation characteristic of the whole element can be improved. Since the rear facet 123 of the blue-violet laser 100 is specified by the outer edge of the area in which the multi-quantum well active layer 105 is removed, the cavity length of the blue-violet laser 100 can be set to predetermined length in accordance with the kind of the blue-violet laser 100.

The blue-violet laser 100 is a GaN-based laser including a ridge-type upper clad (p-type clad layer 108). The chip of the blue-violet laser 100, in this case, the n-type GaN substrate 101 has, for example, a width of 400 ƒÊm and a length of 1,600 ƒÊm. In the foregoing and following embodiments, the width of the chip refers to the length of the substrate in the cross-sectional direction to the waveguide direction (cavity length direction), and the length of the chip refers to the length of the substrate in the direction parallel to the waveguide direction.

In the blue-violet laser 100, the rear facet is etched to remove an unnecessary light emission layer so that the cavity length becomes 600 ƒÊm. In the blue-violet laser 100, a low-reflection coating (not shown) having reflectance of 10% is applied to the front facet 124 from which light is emitted. A high-reflection coating (not shown) having reflectance of 90% is applied to the rear facet 123 of the blue-violet laser 100.

The blue-violet laser 100 has a structure capable of emitting a high light output power of, for example, 200 mW or higher under CW operation.

The red laser 200 is an AlGaInP-based laser including a ridge-type upper clad (p-type clad layer 207). The chip of the red laser 200, in this case, the n-type GaAs substrate 201 has, for example, a width of 250 ƒÊm and a length of 1,500 ƒÊm.

In the red laser 200, a low-reflection coating having reflectance of 7% is applied to the front facet 224 from which light is emitted. A high-reflection coating having reflectance of 95% is applied to the rear facet 223 of the red laser 200.

The red laser 200 has a structure capable of emitting a light output of, for example, 240 mW or higher in pulse operation (for example, pulse width of 30 ns and duty ratio of 30%).

The configuration of the blue-violet laser 100 and the red laser 200 will be described more specifically hereinbelow with reference to FIG. 2.

In the blue-violet laser 100, on the n-type GaN substrate 101 (for example, thickness of about 100 ƒÊm, n=3 ˜10¹⁸ cm⁻³), an n-type buffer layer 102 (for example, an n-type GaN layer, thickness of 1 ƒÊm, n=1 ˜10¹⁸ cm⁻³), an n-type clad layer 103 (for example, an n-type Al_{0.07}Ga_{0.93}N layer, thickness of 1.3 ƒÊm, n=7 ˜10¹⁷ cm⁻³), an n-side optical confinement layer 104 (for example, an n-type GaN layer, thickness of 50 nm, n=5 ˜10¹⁷ cm⁻³), the multi-quantum well active layer 105 made of an In_{0.1}Ga_{0.9}N well (for example, thickness of 3.5 nm) and an In_{0.02}Ga_{0.98}N barrier (for example, thickness of 8.5 nm), a p-side optical confinement layer 106 (for example, a GaN layer, thickness of 80 nm), a p-type overflow protect layer 107 functioning as an electron overflow preventing layer (for example, a p-type Al_{0.16}Ga_{0.84}N layer, thickness of 10 nm, p=5 ˜10¹⁷ cm⁻³), a p-type clad layer 108 (for example, a p-type AlGaN layer, thickness of 500 nm, p=7 ˜10¹⁷ cm⁻³), and a p-type contact layer 109 (for example, a p-type GaN layer, thickness of 100 nm, and p=1 ˜10¹⁸ cm⁻³) are laminated. In the specification, “n=” and “p=” denote concentration of n-type carriers (electrons) and p-type carriers (positive holes) in a layer, respectively.

For transverse mode control, the p-type clad layer 108 is etched to some point in the thickness direction, thereby forming a ridge 121. The p-type contact layer 109 is provided at the apex of the ridge 121, that is, on the top face of the p-type clad layer 108. Further, a silicon oxide film 110 covering the side face of the p-type clad layer 108 and the bottom is laminated on the outside of the ridge 121.

The p-type contact layer 109 is provided with a p-side electrode 111 made of palladium/platinum/gold (Pd/Pt/Au) in this order from the contact layer side. On the back side of the n-type GaN substrate 101, an n-side electrode 112 constructed by titanium/platinum/gold (Ti/Pt/Au) in this order from the substrate side is formed.

On the other hand, in the red laser 200, on the n-type GaAs substrate 201 (for example, thickness of about 120 ƒÊm, n=2 ˜10¹⁸ cm⁻³), an n-type buffer layer 202 (for example, an n-type GaAs layer, thickness of 500 nm, n=1 ˜10¹⁸ cm⁻³), an n-type clad layer 203 (for example, an n-type (Al_{0.7}Ga_{0.3})_{0.47}In_{0.53}P layer, thickness of 2 ƒÊm, n=8 ˜10¹⁷ cm⁻³), an n-side optical confinement layer 204 (for example, an (Al_{0.5}Ga_{0.5})_{0.47}In_{0.53}P layer, thickness of 30 nm), the multi-quantum well active layer 205 made of a GaInP well and an AlGaInP barrier, a p-side optical confinement layer 206 (for example, an (Al_{0.5}Ga_{0.5})_{0.47}In_{0.53}P layer, thickness of 30 nm), a p-type clad layer 207 (for example, a p-type (Al_{0.7}Ga_{0.3})_{0.47}In_{0.53}P layer, thickness of 1.5 ƒÊm, p=8 ˜10¹⁷ cm⁻³), and a p-type contact layer 208 (for example, a p-type GaAs layer, thickness of 400 nm, and p=5 ˜10¹⁸ cm⁻³) are laminated.

In the red laser 200, for transverse mode control, the p-type clad layer 207 is etched to some point in the thickness direction, thereby forming a ridge 221. The p-type contact layer 208 is provided at the apex of the ridge 121, that is, on the under face of the p-type clad layer 207. Further, a silicon oxide film 209 covering the side face of the p-type clad layer 207 and the bottom is laminated on the outside of the ridge 221.

The p-type contact layer 208 is provided with a A-side electrode 210 made of Ti/Pt/Au in this order from the contact layer side. On the back side of the n-type GaAs substrate 201, an n-side electrode 211 constructed by gold germanium/nickel/gold (AuGe/Ni/Au) in this order from the substrate side is formed.

The red laser 200 is fusion-bonded with the p-side down onto the blue-violet laser 100 via a fusion material 113 made of gold (Au) and tin (Sn). The shorter the interval between light emitting points of the blue-violet laser 100 and the red laser 200 is, the more it is advantageous for adjustment of the optical axis of an optical pickup. Therefore, it is preferable to adjust the formation position of a ridge in the chip of each of lasers so that the light emitting points are close as much as possible.

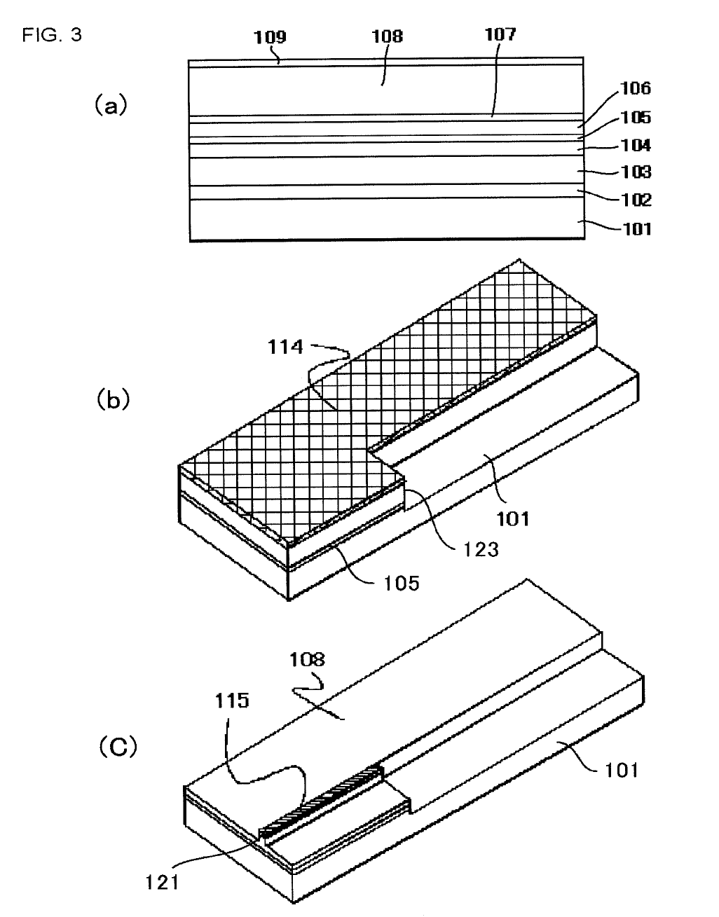

Next, a method of manufacturing the two-wavelength semiconductor laser 1 will be described. FIGS. 3 to 6 are diagrams showing the method of manufacturing the two-wavelength semiconductor laser 1. FIGS. 3(a) to 3(c) and

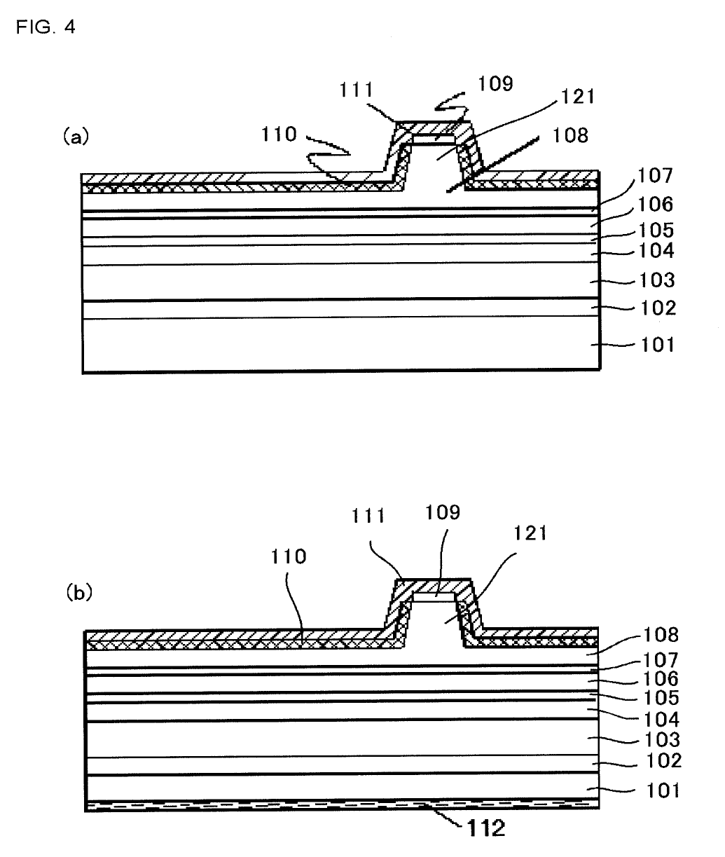

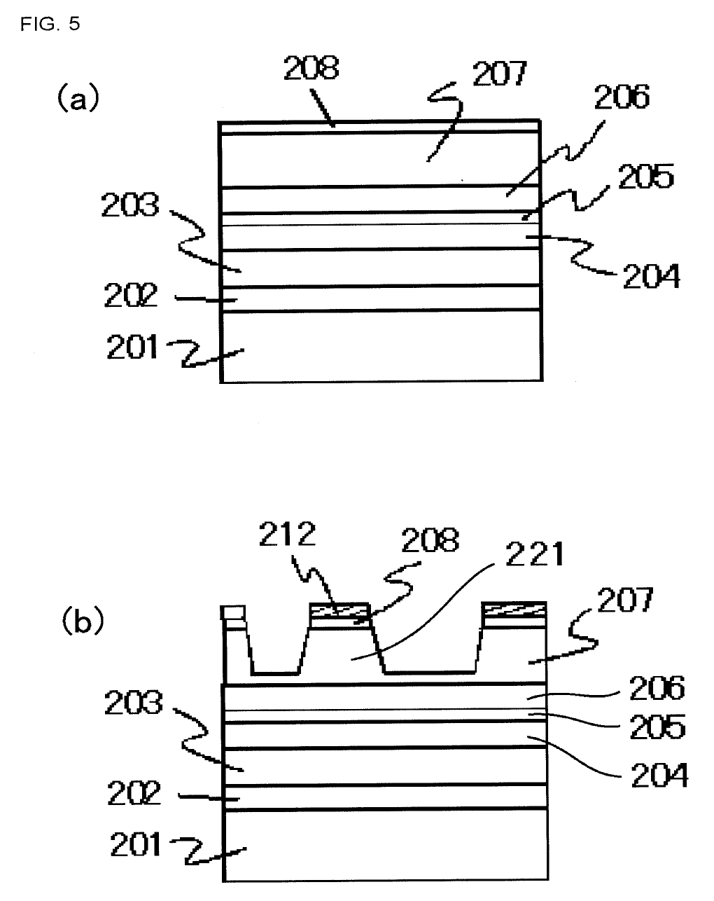

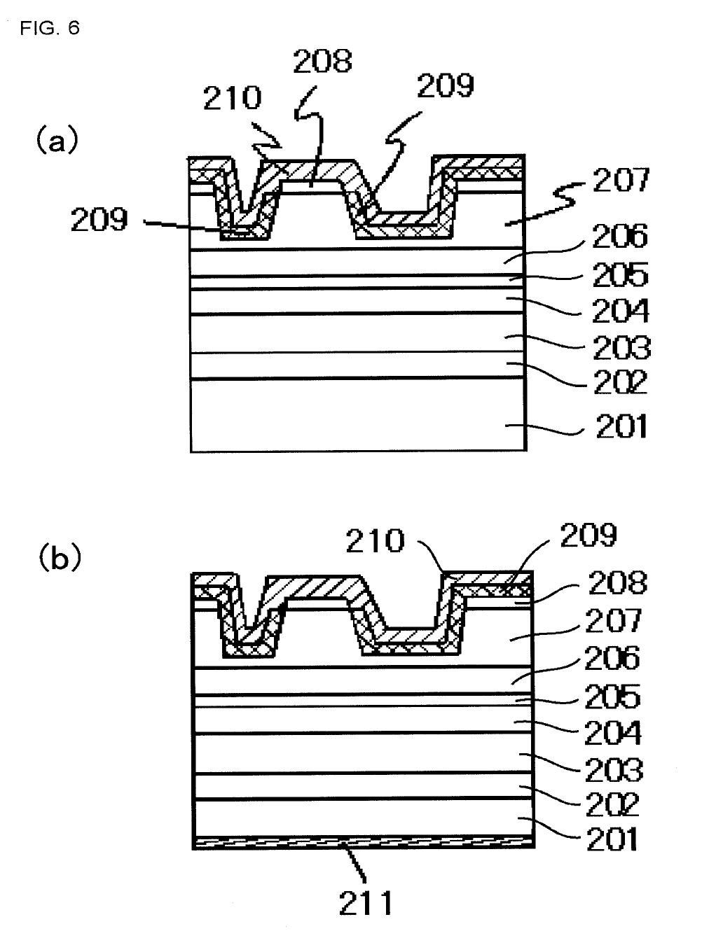

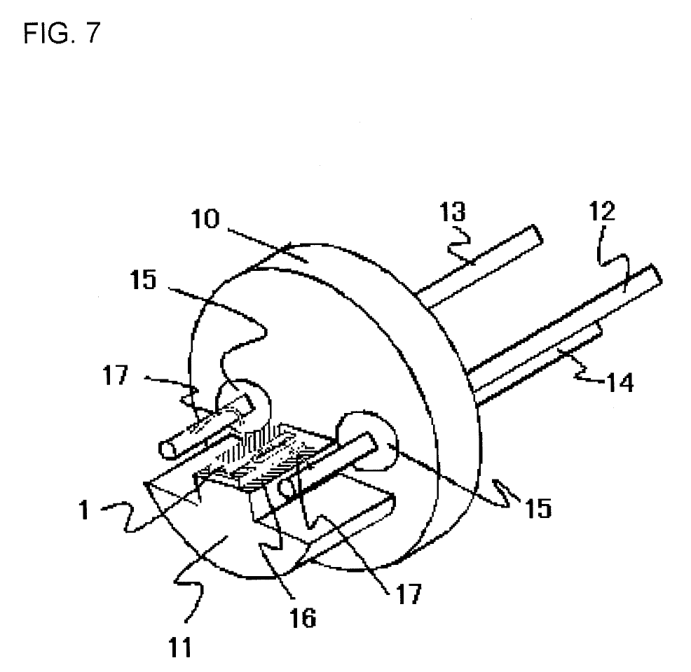

FIGS. 4(a) and 4(b) are diagrams showing processes of manufacturing the GaN-based blue-violet laser 100. FIGS. 5(a) and 5(b) and FIGS. 6(a) and 6(b) are cross-sectional views showing processes of manufacturing the AlGaInP-based red laser 200.

First, with reference to FIGS. 3(a) to 3(c) and FIGS. 4(a) and 4(b), processes of manufacturing the GaN-based blue-violet laser 100 will be described. In the manufacturing processes, the rear facet 123 is formed by dry etching and the front facet 124 from which light is taken is formed by cleavage.

On the n-type GaN substrate 101 having a thickness of, for example, about 400 ƒÊm, the n-type buffer layer 102, n-type clad layer 103, n-side optical confinement layer 104, multi-quantum well active layer 105, optical confinement layer 106, that is, non-doped p-side GaN layer, p-type AlGaN electronic barrier layer 107, p-type clad layer 108, and p-type contact layer 109 are sequentially grown (FIG. 3(a)). In FIGS. 3(b) and 3(c), some of the grown layers are not shown.

For the crystal growth, for example, the metal-organic vapor phase epitaxy (MOVPE) method is used. As the material, for example, trimethyl aluminum (TMAl), trimethyl gallium (TMGa), triethylgallium (TEGa), trimethylindium (TMIn), and ammonia (NH₃) are used. As n-type and p-type dopants, for example, silicon (Si) and magnesium (Mg) are used. As the materials, for example, silane (SiH₄) and cyclopentadiethyl magnesium (Cp₂Mg) are used. As a carrier gas, hydrogen or nitrogen is used according to the composition of each of the grown layers.

After that, the rear facet 123 of the blue-violet laser 100 is formed by dry etching. First, by using a method such as thermal chemical vapor deposition (thermal CVD), plasma CVD, sputtering, or electronic beam deposition, the silicon oxide film 114 is deposited. By using a stepper or photolithography such as contact exposure, a predetermined area in the silicon oxide film 114 is selectively removed by etching. The planar shape of the silicon oxide film 114 after etching is, for example, an L shape. Using the silicon oxide film 114 as a mask, the grown layer is removed to the n-type GaN substrate 101 by dry etching, thereby reducing the grown layer length (FIG. 3(b)). As shown in FIG. 3(b), the etched side face becomes the rear facet 123 of the blue-violet laser 100. It is therefore desirable to etch the side face as smoothly as possible and so as to become perpendicular to the substrate in plane direction.

Subsequently, the ridge 121 is formed. First, a stripe-shaped silicon oxide film 115 having a width of 1.5 ƒÊm is formed on the p-type contact layer 19. The silicon oxide film 115 is formed so as to extend in the cavity length direction in the area where the length of the grown layer is reduced by the process described above with reference to FIG. 3(b). The silicon oxide film 115 is formed as follows. After the silicon oxide film 114 is removed, another silicon oxide film is deposited again and is allowed to selectively remain only in the predetermined area by photolithography. Alternatively, in stead of the method of forming another silicon oxide film, after the process shown in FIG. 3(b), the silicon oxide film 114 may be further processed in a predetermined shape by photolithography.

Using the silicon oxide film 115 as a mask, a part of the p-type contact layer 109 and the p-type clad layer 108 is etched by dry etching, thereby forming the ridge 121 (FIG. 3(c)).

Then, the p-side electrode 111 is formed. First, the stripe-shaped silicon oxide film 115 is removed. Another silicon oxide film 110 is deposited again on the entire surface of the n-type GaN substrate 101. The silicon oxide film 110 on the ridge top is removed by etching to expose the p-type contact layer 109. On the p-type contact layer 109, metal films constructing the p-side electrode 111 are deposited (FIG. 4(a)).

To facilitate cleavage, the n-type GaN substrate 101 is polished to reduce the thickness to, for example, about 100 ƒÊm. The polished face is subject to a cleaning process. After that, the n-side electrode 112 which is in contact with the polished face and covers the face is formed (FIG. 4(b)). Next, for facet coating, the wafer is cleaved so that the ridges 121 are arranged like bars side by side. In this case, the wafer is cleaved in a position apart from the position of the rear facet 123 formed by dry etching by 600 ƒÊm, thereby forming the front facet 124. As a result, the cavity length of the GaN-based blue-violet laser 100 becomes 600 ƒÊm.

The opposite side is also cleaved so that the length of the chip, that is, the length in the cavity length direction of the n-type GaN substrate 101 becomes 1,600 ƒÊm. A low-reflection coating having reflectance of 10% is applied to the front facet 124, and a high-reflection coating having reflectance of 90% is applied to the rear facet 123. As a material having low refractive index among coating materials, for example, alumina, silicon oxide, aluminum nitride, magnesium fluoride, or calcium fluoride is used. As a material having high refractive index in the coating material, for example, titanium oxide, zirconium oxide, hafnium oxide, or the like is used. Finally, cleavage is performed to divide the wafer in which the plurality of ridges 121 are arranged in parallel with each other like bars into a plurality of chips. By the above-described procedure, the blue-violet laser 100 is obtained.

With reference to FIGS. 5(a), 5(b), 6(a), and 6(b), processes of manufacturing the AlGaInP-based red laser 200 will be described.

First, on the n-type GaAs substrate 201 having a thickness of, for example, about 350 ƒÊm, the n-type GaAs 202, n-type clad layer 203, n-side optical confinement layer 204 (for example, AlGaInP layer), multi-quantum well active layer 205, p-side optical confinement layer 206 (for example, AlGaInP layer), p-type clad layer 207, and p-type contact layer 208 are sequentially crystal-grown (FIG. 5(a)).

For the crystal growth, for example, the MOVPE method is used. As the material, for example, TMAl, TEGa, TMIn, arsine (AsH₃), or phosphine (PH₃) is used. As n-type and p-type dopants, for example, Si and zinc (Zn) are used, respectively. As the materials, for example, disilane (Si₂H₆) and diethylzinc (DEZn) are used. As a carrier gas, for example, hydrogen is used.

Subsequently, the ridge 221 is formed. First, a silicon oxide film 212 is deposited by using thermal CVD method, plasma CVD method, sputtering method, electronic beam deposition method, or the like. By selectively removing a predetermined area in the silicon oxide film 212 using a stepper or photolithography such as contact exposure, the silicon oxide film 212 is processed in a stripe shape extending in the cavity length direction and having a width of 1.5 ƒÊm. Using the silicon oxide film 212 as a mask, a part of the p-type contact layer 208 and the p-type clad layer 207 is selectively removed by dry etching or the like, thereby forming the ridge 221 (FIG. 5(b)).

Next, the p-side electrode 210 is formed. First, the stripe-shaped silicon oxide film 212 is removed. After that, another silicon oxide film 209 is deposited again. The silicon oxide film 209 on the ridge top is selectively removed by etching to expose the p-type contact layer 208. On the p-type contact layer 208, metal films constructing the p-side electrode 210 are deposited (FIG. 6(a)).

To facilitate cleavage, the n-type GaAs substrate 201 is polished to reduce the thickness to, for example, about 120 ƒÊm. The polished face is subjected to a cleaning process. After that, the n-side electrode 211 which is in contact with the polished face and covers the face is formed (FIG. 6(b)). Next, for facet coating, cleavage is performed so that the cavity length becomes 1,500 ƒÊm. A low-reflection coating having reflectance of 7% is applied to the front facet 224, and a high-reflection coating having reflectance of 95% is applied to the rear facet 223. Finally, cleavage is performed to divide the wafer in which a plurality of ridges 221 are arranged like bars into a plurality of chips. By the above-described procedure, the red laser 200 is obtained.

The red laser 200 employs a window structure and a current non-injecting structure to prevent facet degradation.

The red laser 200 obtained in such a manner is fusion-bonded with the p-side down to the p side of the blue-violet laser 100 by using the fusion material 113 as shown in FIG. 2. As a result, the two-wavelength semiconductor laser 1 shown in FIG. 1 is obtained.

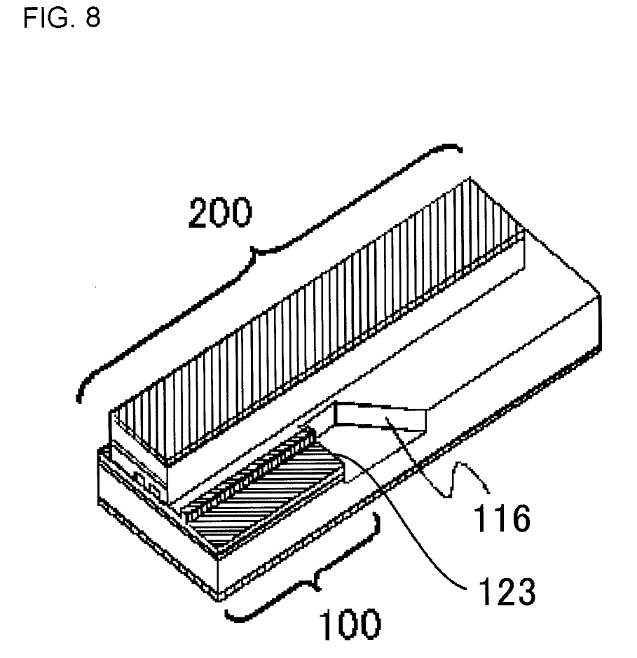

A package including the two-wavelength semiconductor laser 1 will now be described. FIG. 7 is a bird's-eye view showing a state where the two-wavelength semiconductor laser 1 of the present embodiment is assembled in a package having a diameter of 5.6 mm.

The material of a body 10 of the package is, for example, iron. The material of a supporting member 11 and feedthroughs 12, 13, and 14 is, for example, copper. The surface of each of the body 10, the supporting member 11, and the feedthroughs is coated with gold.

Each of the feedthroughs 12 and 13 is attached to the body 10 via an insulator 15 made of ceramics or the like. In such a manner, the feedthroughs and the body 10 are insulated from each other. The feedthrough 14 is connected to the body 10 and is electrically connected to the supporting member 11.

The face of the n-side electrode 112 of the blue-violet laser 100 in the two-wavelength semiconductor laser 1 is fusion-bonded to the supporting member 11 via a fusion material 16. As the fusion material 16, for example, gold tin, lead tin, or the like, which has a low melting point, is used. Further, the feedthrough 12 and the p-side electrode 111 of the blue-violet laser 100 are bonded to each other via a gold wire 17. The feedthrough 13 and the n-side electrode 211 of the red laser 200 are bonded to each other via the gold wire 17.

In the two-wavelength semiconductor laser 1 of the present embodiment, when a positive voltage is applied to the feedthrough 12 and a negative voltage is applied to the feedthrough 14, the blue-violet laser 100 performs laser oscillation. When a positive voltage is applied to the feedthrough 12 and a negative voltage is applied to the feedthrough 13, the red laser 200 performs laser oscillation.

In the two-wavelength semiconductor laser 1 in which the blue-violet laser 100 and the red laser 200 are integrated, the length of the chip of the GaN-based blue-violet laser 100 playing the role of a heat sink is equal to or longer than that of the chip of the AlGaInP-based red laser 200 which is fusion-bonded to the chip of the blue-violet laser 100. Consequently, heat generated by the chip of the red laser 200 is efficiently dissipated from the supporting member 11 via the blue-violet laser 100. Therefore, the radiation performance of the red laser 200 having a long cavity length of 1,500 ƒÊm is assured, and a high output power characteristic can be realized.

In the patent document 1 described in the background art, in a configuration of bonding a semiconductor light emitting element having a wavelength of 780 nm to a semiconductor light emitting element having a wavelength of 650 nm, by adjusting the positions of the front facets of the semiconductor light emitting elements to offset the rear facets, a bonding area is assured. In the configuration, however, each of the cavity lengths of the semiconductor light emitting elements is equal to the length of the substrate and is determined depending on the length of the substrate. Due to this, in the case of using a GaN-based blue-violet laser or the like for a substrate having a large area, the cavity length increases. Consequently, it is concerned that the laser characteristic and reliability of the blue-violet laser may not be sufficiently assured.

In contrast, in the embodiment of the present invention, in the blue-violet laser 100, although the length of the chip is long as 1,600 ƒÊm, the rear facet 123 is formed by dry etching so that the cavity length becomes 600 ƒÊm. By forming the rear facet 123 by dry etching or the like so that the cavity length necessary for laser oscillation is shorter than the length of the chip, reduction in waveguide loss, decrease in the number of dislocations of propagation from the n-type GaN substrate 101 to the waveguide stripe, laser oscillation with high-efficiency, low drive current, and high reliability can be realized. Therefore, the laser characteristic and reliability equivalent to those of a normal GaN-based blue-ultraviolet laser having the cavity length of 600 ƒÊm can be realized.

As described above, by the two-wavelength semiconductor laser 1, an integrated laser assuring balance of thermal conductivity and cavity length and having excellent laser characteristic and reliability is realized.

Since the rear facet 123 of the blue-violet laser 100 is formed by etching in the present embodiment, the rear facet 123 is formed with excellent controllability and variations in the cavity length in the blue-ultraviolet laser 100 at the time of manufacturing can be excellently suppressed.

Although the technical field is different, the patent document 2 describes the technique of forming the etched mirror faces of two lasers formed monolithically by the same etching process and making the positions of the mirror faces different to the cavity length direction. In this case, two lasers have to be constructed by a material which can be etched by the same etching process.

In contrast, in the present embodiment, semiconductor lasers are formed on different substrates, and one of the substrates is bonded to the other substrate. Consequently, the positions of facets and cavity lengths can be designed more flexibly in accordance with the characteristics of the semiconductor lasers, and the semiconductor lasers can be manufactured stably. In the GaN-based blue-violet laser 100, an area in which the multi-quantum well active layer 105 is formed and an absent area in which the multi-quantum well active layer 105 is removed are provided. The red laser 200 is disposed in the area in which the multi-quantum well active layer 105 is formed. Therefore, the absent area can be effectively used as the radiation area of the blue-violet laser 100 and the red laser 200.

In the two-wavelength semiconductor laser 1, the front facet 124 of the blue-violet laser 100 and the front facet 224 of the red laser 200 are flush with the facet of the n-type GaN substrate 101. The facets are arranged on the same straight line. Consequently, the focal point of emitting light from the blue-violet laser 100 and that of emitting light from the red laser 200 are positioned in the same plane. Thus, the device configuration of the light reception system can be simplified.

In the present embodiment, the case where the GaN-based blue-violet laser 100 and the AlGaInP-based red laser 200 are integrated has been described. The laser structure integrated on the n-type GaN substrate 101 is not limited to an AlGaInP system. For example, an AlGaAs-based, GaInAs-based, AlGaInAs-based, InGaAsP-based, InGaAsN-based, or InGaAsNSb-based laser may be used.

More specifically, a two-wavelength semiconductor laser in which an AlGaAs-based infrared laser is integrated in place of the AlGaInP-based red laser 200 may be used. In this case, since thermal conductivity of AlGaAs is higher than that of AlGaInP, also in the configuration where the cavity length is, for example, 900 ƒÊm and is shorter than that of the AlGaInP-based laser, for example, pulse operation (pulse width: 50 ns, duty ratio: 50%) 200 mW can be performed. Therefore, the length of the chip of the GaN-based blue-violet laser 100, that is, the length in the cavity length direction of the n-type GaN substrate 101 can be decreased to 900 ƒÊm or longer. In this case as well, the AlGaAs-based infrared laser is integrated on the n-type GaN substrate 101, and the radiation performance can be sufficiently assured.

In the present embodiment, the case of the two-wavelength semiconductor laser 1 has been described in which the length of the chip in the waveguide direction (cavity length direction) of the GaN-based blue-violet laser 100 is 1,600 ƒÊm and is longer than that of the chip of the AlGaInP-based red laser 200 which is fusion-bonded to the chip. More specifically, the case where the length of the chip of the red laser 200 is equal to that of the waveguide and the cavity length, and is 1,500 ƒÊm has been described.

However, as long as the radiation performance of the red laser 200 can be sufficiently assured, the present invention is not limited to the configuration that L0 is larger than L2 but may employ a configuration that L0 is equal to L2. Alternatively, a configuration that strict lengths of the chips have opposite relation (L0<L2) may be used. From the viewpoint of obtaining the radiation performance more reliably, for example, the length in the cavity length direction of the n-type GaN substrate 101 can be set to 90% or more, preferably, 95% or more of the length in the cavity length direction of the n-type GaAs substrate 201. More specifically, the length of the n-type GaN substrate 101 may be set to 1,500 ƒÊm and the length of the n-type GaAs substrate 201 may be set to 1,520 ƒÊm. In this case, when the red laser 200 is integrated on the chip of the blue-violet laser 100, 10 ƒÊm of the front facet side and 10 ƒÊm of the rear facet side of the red laser 200 lie off the chip of the blue-violet laser 100. In such a configuration, since a large part of the substrate 201 of the red laser 200 is in contact with the blue-violet laser 100, radiation performance sufficient enough not to cause a problem in practice is assured. In such a case as well, the lengths of the chips can be considered as the same.

The position of the rear facet 223 of the red laser 200 and that of the facet of the n-type GaN substrate 101 may be coincided with each other, and the front facet 124 of the blue-violet laser 100 and the front facet 124 of the red laser 200 may be coincided with the same facet of the n-type GaN substrate 101. This configuration is expressed as L0=L2. In such a manner, while assuring sufficient radiation characteristic of the red laser 200, the two-wavelength semiconductor laser 1 can be miniaturized as a whole.

In the following, the points different from the first embodiment will be mainly described.

### Second Embodiment

FIG. 8 is a bird's-eye view showing a configuration of a two-wavelength semiconductor laser of the present embodiment. The basic configuration of the two-wavelength semiconductor laser is similar to that of the two-wavelength semiconductor laser in the first embodiment but is different with respect to the following point. At the time of forming the rear facet 123 of the blue-violet laser 100 by dry etching, a reflection mirror 116 whose surface facing the rear facet 123 is inclined at 45o with respect to the rear facet is formed.

In FIG. 8, by providing the reflection mirror 116 in the area from which the multi-quantum well active layer 105 is removed on one of the faces of the n-type GaN substrate 101, the area from which the multi-quantum well active layer 105 is removed can be effectively used. Light emitted from the rear facet 123 of the blue-violet laser 100 is reflected by the reflection mirror 116, goes out from the side of the chip, and is received by a light receiving element (not shown). The light can be used as monitor light of laser operation.

### Third Embodiment

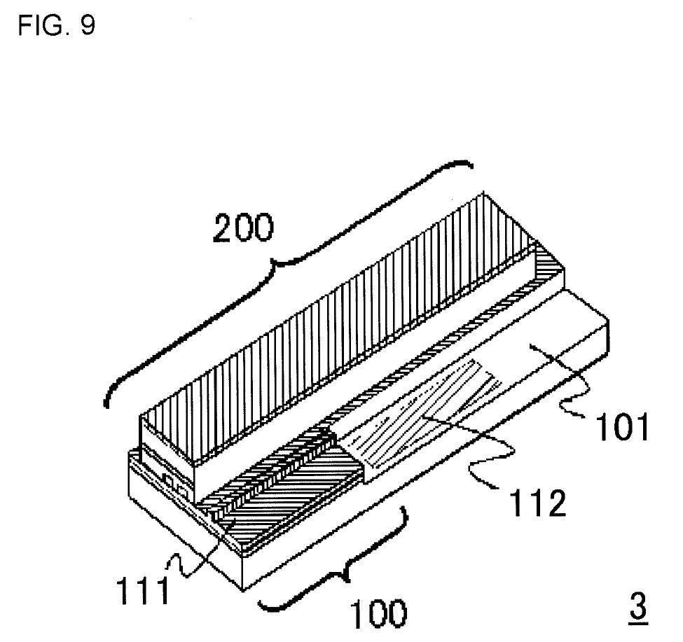

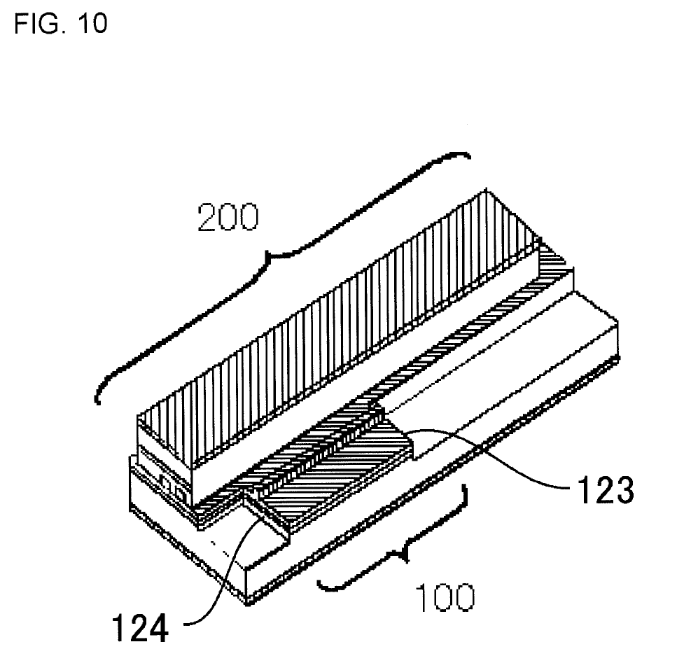

FIG. 9 is a bird's-eye view showing a configuration of a two-wavelength semiconductor laser 3 of the present embodiment. The basic configuration of the two-wavelength semiconductor laser is similar to that of the two-wavelength semiconductor laser 1 in the first embodiment and the AlGaInP-based red laser 200 is integrated on the chip of the GaN-based blue-violet laser 100. The difference from the first embodiment is that the n-side electrode 112 of the blue-violet laser 100 is formed on the n-type GaN substrate 101 in the area etched for forming the rear facet 123, not on the back side of the n-type GaN substrate 101.

With such a configuration, by using the same electrode material (for example, Ti/Pt/Au) for the p-side electrode 111 and the n-side electrode 112, the p-side electrode 111 and the n-side electrode 112 can be formed simultaneously. As a result, the number of electrode forming processes can be reduced. In addition, the area from which the multi-quantum well active layer 105 is removed on one of the faces of the n-type GaN substrate 101 can be effectively used.

Also in the case where the material of the p-side electrode 111 and that of the n-side electrode 112 are different, the manufacturing order can be arbitrarily selected. As a result, there is an advantage such that the optimum process minimizing contact resistance such as an alloy parameter can be applied to each of the electrodes. In the process described with reference to FIG. 3, the electrode on the ridge side (in the case of FIG. 3, the p-side electrode 111) is formed first. In this way, the electrode on the ridge side which requires processes such as deposition and patterning of the silicon oxide film 110 can be formed before polishing the substrate. Thus, manufacturing stability can be improved.

The present embodiment has another advantage. At the time of assembling the blue-violet laser 100 into a package, by electrically isolating the supporting member 11 or fusion-bonding the blue-violet laser 100 to the supporting member 11 via a semi-insulating sub-mount such as a heat sink of aluminum nitride, the blue-violet laser 100 can be electrically floated.

### Fourth Embodiment

FIG. 10 is a bird's-eye view showing a configuration of a two-wavelength semiconductor laser of the present embodiment. The basic configuration of the two-wavelength semiconductor laser is similar to that of the two-wavelength semiconductor laser 1 in the first embodiment and the AlGaInP-based red laser 200 is integrated with the p-side down on the chip of the GaN-based blue-violet laser 100. In FIG. 10, the point different from the first embodiment is that both of the front facet 124 and the rear facet 123 of the blue-violet laser 100 are formed by dry etching. The front facet 124 is retreated to the inside of the n-type GaN substrate 101 compared to the front facet 224.

With the configuration, the cavity length is determined by the etching process. Thus, it is unnecessary to control the cavity length strictly during cleaving the wafer to the chip. Since the GaN substrate of the blue-violet laser 100 is very hard, in the case where the wafer thickness after polishing is not uniform or the cleavage conditions are poor, it is concerned that a blemish (step) is formed in a cleavage surface. In contrast, in the present embodiment, there is not such a concern. The controllability on the cavity length of the blue-violet laser 100 can be further improved by etching.

The area from which the multi-quantum well active layer 105 is removed is provided in both of the facet face 123 and the front facet 124 of the n-type GaN substrate 101. Thus, variations in radiativity in the two-wavelength semiconductor laser 1 can be suppressed.

### Fifth Embodiment

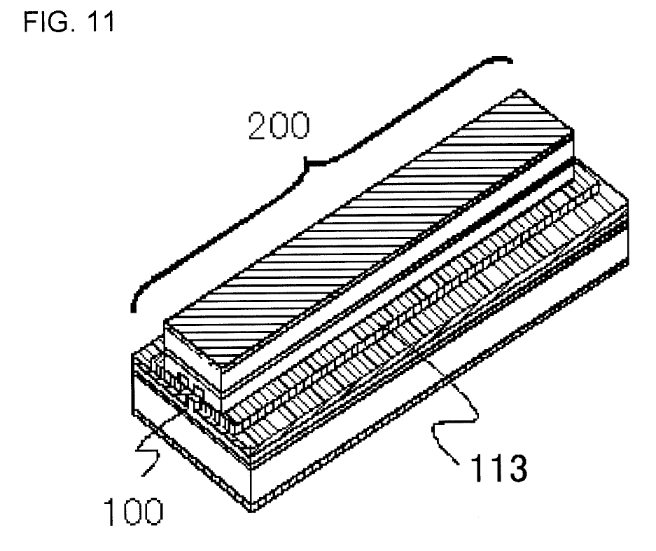

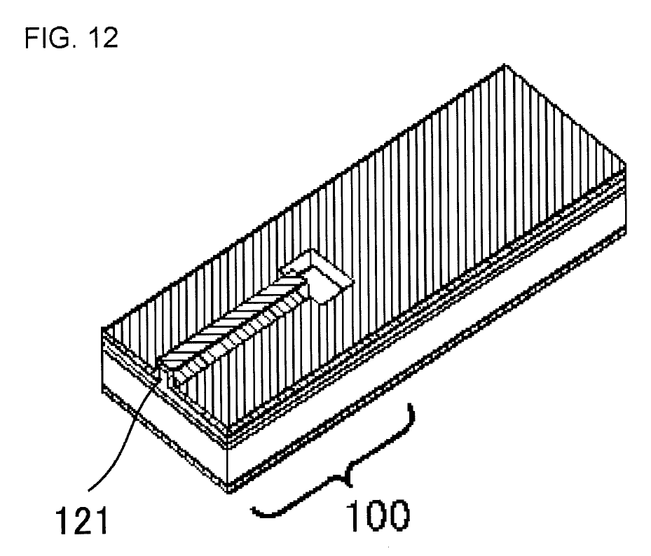

FIG. 11 is a bird's-eye view showing a configuration of a two-wavelength semiconductor laser of the present embodiment. FIG. 12 is a bird's-eye view showing a configuration of the blue-violet laser 100 used for the two-wavelength semiconductor laser of FIG. 11.

The basic configuration of the two-wavelength semiconductor laser is similar to that of the two-wavelength semiconductor laser 1 in the first embodiment, and the AlGaInP-based red laser 200 is integrated with the p-side down on the chip of the GaN-based blue-violet laser 100 via the fusion material 113. In FIG. 11, the point different from the first embodiment is that the red laser 200 is fusion-bonded immediately above a ridge waveguide (the ridge 121 in FIG. 12) of the blue-violet laser 100.

As shown in FIG. 12, the multi-quantum well active layer 105 is absent in a center area of the substrate face, and the planar shape of the absent area is almost rectangular. In one of the faces of the n-type GaN substrate 101, the multi-quantum well active layer 105 on and around the rear facet 123 of the blue-violet laser 100 is removed. The multi-quantum well active layer 105 is removed rearward in the cavity length direction from the rear facet 123 of the blue-violet laser 100, that is, so as to be apart from the blue-violet laser 100 in the cavity length direction.

By fusion-bonding the red laser 200 to the position just above the ridge 121, the light emission point interval between the blue-violet laser 100 and the red laser 200 is shortened. Consequently, the configuration is very advantageous from the viewpoint of adjusting the optical axis of the optical pickup. Also in FIG. 12, to set the cavity length of the blue-violet laser 100 to 600 ƒÊm, the rear facet 123 is formed by etching using the method described in the first embodiment. In FIG. 12, the area to be etched has a width of about 20 ƒÊm and a length of about 10 ƒÊm and is narrower than that in the first embodiment. As a result, the radiation performance of the red laser 200 which is fusion-bonded just above the ridge 121 can be assured. Therefore, a more excellent output characteristic can be obtained.

### Sixth Embodiment

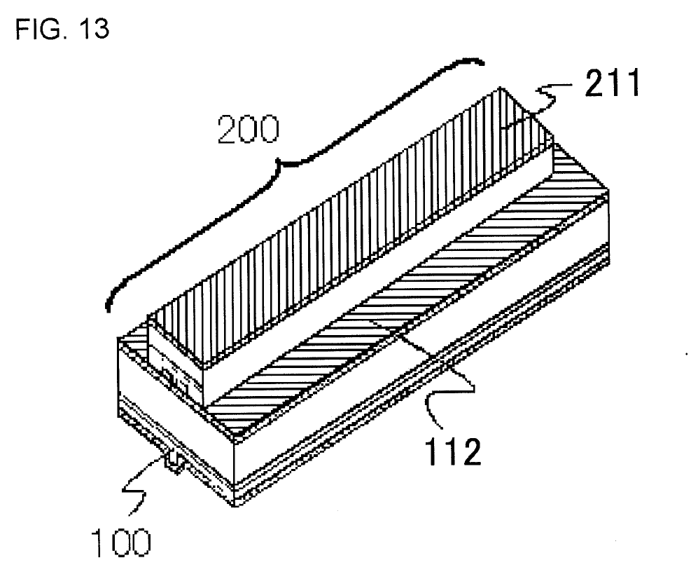

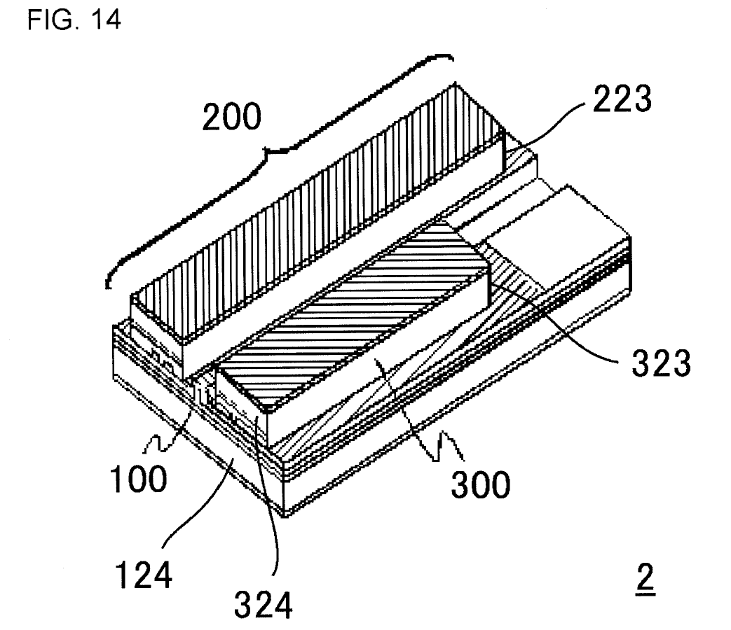

FIG. 13 is a bird's-eye view showing a configuration of a two-wavelength semiconductor laser of the present embodiment. The basic configuration of the two-wavelength semiconductor laser is similar to that of the two-wavelength semiconductor laser 1 in the first embodiment. The red laser 200 is fusion-bonded with the p-side down on the chip of the blue-violet laser 100 via the fusion material. The blue-violet laser 100 and the red laser 200 have the same structures as those used in the fourth embodiment. The point different from the fourth embodiment is that the multi-quantum well active layers 105 and 205 are provided on different sides of the n-type GaN substrate 101. Specifically, the red laser 200 is fusion-bonded to the back side of the substrate of the blue-violet laser 100.

Since the back side of the n-type GaN substrate 101 is flat, by fusion-bonding the red laser 200 to the back side, the whole chip can be bonded to the blue-violet laser 100 without causing large distortion in the ridge of the red laser 200. Therefore, deterioration in the yield during assembling can be suppressed.

In the case of assembling the two-wavelength semiconductor laser of the present embodiment into a package, it is assembled with the p-side down of the blue-violet laser 100 into, for example, the package having the diameter of 5.6 mm shown in FIG. 5. In this case, the laser is fusion-bonded to the supporting member 11 directly or via a sub mount. Thus, there is an advantage that the radiation performance of the blue-violet laser 100 improves and the high output power characteristic and the temperature characteristic improve as compared with the case of the fourth embodiment.

In the forgoing embodiments, the case of the two-wavelength semiconductor laser has been described as an example. The embodiments of the present invention are not limited to the case of the two-wavelength semiconductor laser but may be also applied to an integrated semiconductor laser in which “n” pieces of second, third, [symbol] c, and the (n+1)th semiconductor lasers (n=1, 2, 3, [symbol] c) are bonded on the chip of the blue-violet laser 100, in this case, on the n-type GaN substrate 101. When the cavity length of the (n+1)th semiconductor laser integrated is set as L(n+1), L0 is equal to or larger than L(n+1).

Embodiments of a three-wavelength semiconductor laser will be described below.

### Seventh Embodiment

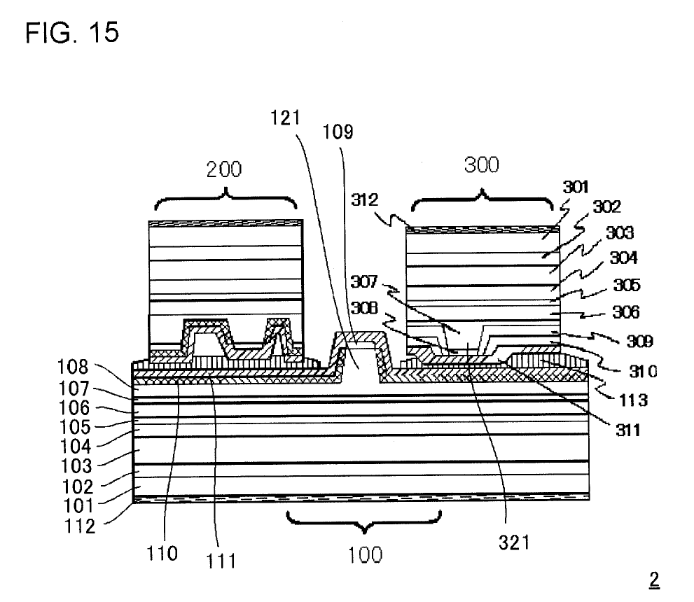

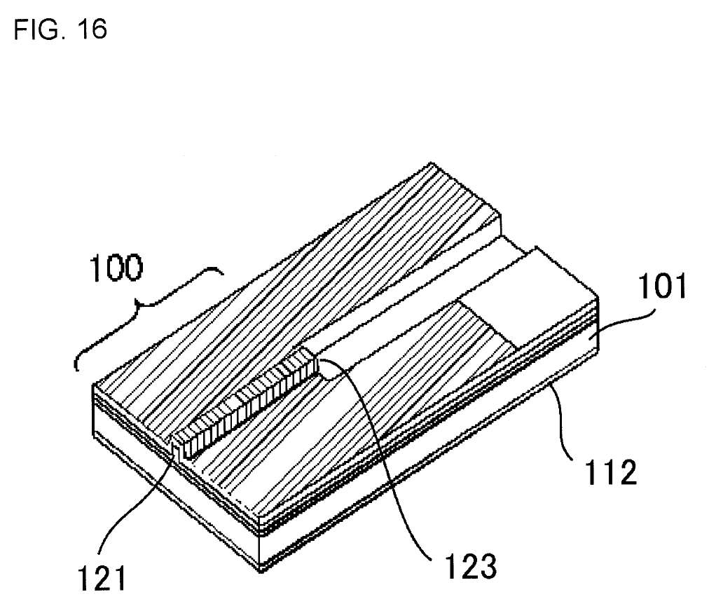

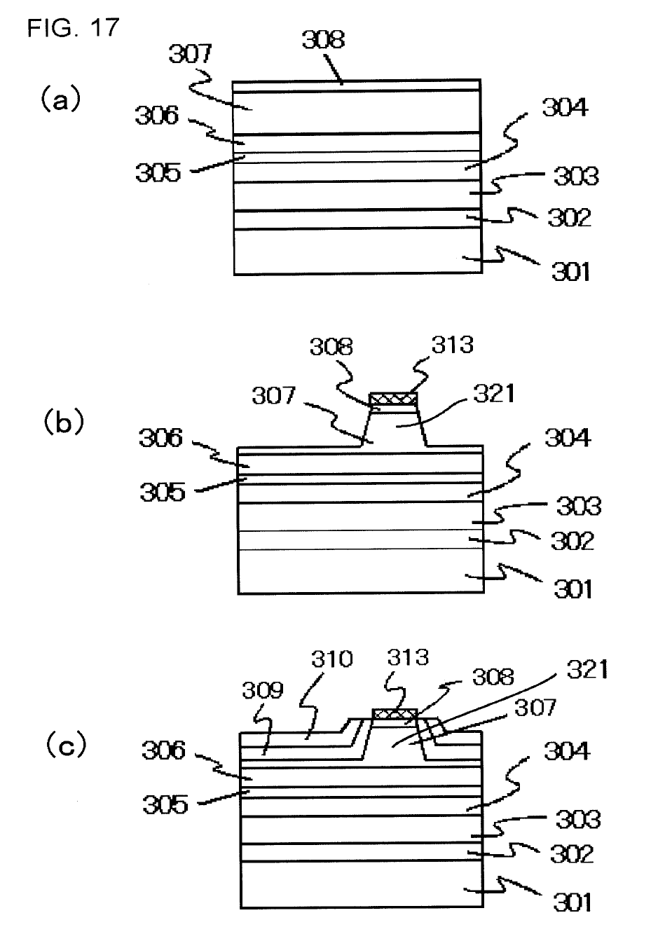

FIG. 14 is a bird's-eye view showing a configuration of a three-wavelength semiconductor laser 2 of the present embodiment. FIG. 15 is a cross-sectional view of the three-wavelength semiconductor laser 2 shown in FIG. 14. FIG. 16 is a bird's-eye view of the blue-violet laser 100 of the three-wavelength semiconductor laser 2 of FIG. 15.

The three-wavelength semiconductor laser 2 includes a third active layer (multi-quantum well active layer 305) provided on one of the faces of a third semiconductor substrate (n-type GaAs substrate 301), and also includes a third laser structure (infrared laser 300) having a cavity length of L3. The red laser 200 and the infrared laser 300 are provided on the same side of the n-type GaN substrate 101. Specifically, the AlGaInP-based red laser 200 and the AlGaAs-based infrared laser 300 are integrated on the chip of the GaN-based blue-violet laser 100. Both of the red laser 200 and the infrared laser 300 are fusion-bonded with the p-side down to the p-side of the blue-violet laser 100. The red laser 200, the blue-violet laser 100, and the infrared laser 300 are arranged side by side in this order so that their cavity length directions are parallel with each other.

The chip of the blue-violet laser 100 has, for example, a width of 400 ƒÊm and a length of 1,600 ƒÊm. In the blue-violet laser 100, the rear facet 123 is formed by etching so that the cavity length becomes 600 ƒÊm (FIG. 16). By the etching, an unnecessary light emission layer is removed. The planar shape of the multi-quantum well active layer 105 is an almost U shape. In the blue-violet laser 100, a low-reflection coating having reflectance of 10% is applied to the front facet 124 from which light is emitted. A high-reflection coating having reflectance of 90% is applied to the rear facet 123 (shown in FIG. 16).

As shown in FIG. 15, the laminated structure of the blue-violet laser 100 is similar to that of the first embodiment (FIG. 2). However, in FIG. 15, unlike the case of FIG. 2, a ridge structure (ridge 121) of the blue-violet laser 100 is formed almost in the center of the chip. The light emission point of the red laser 200 and the light emission point of the infrared laser 300 are disposed bilaterally symmetrically with respect to the light emission point of the blue-violet laser 100 as a center.

The structure of the red laser 200 is similar to that of the element of the first embodiment, and the chip of the red laser 200 has, for example, a width of 150 ƒÊm and a length of 1,500 ƒÊm. In the red laser 200, a low-reflection coating having reflectance of 7% is applied to the front facet 224 from which light is emitted. A high-reflection coating having reflectance of 95% is applied to the rear facet 223.

The chip of the infrared laser 300 has, for example, a width of 150 ƒÊm and a length of 900 ƒÊm. In the infrared laser 300, a low-reflection coating having reflectance of 5% is applied to a front facet 324 from which light is emitted. A high-reflection coating having reflectance of 95% is applied to a rear facet 323.

As shown in FIG. 15, in the infrared laser 300, on the n-type GaAs substrate 301 (for example, thickness of about 120 ƒÊm, n=2 ˜10¹⁸ cm⁻³), an n-type buffer layer 302 (for example, an n-type GaAs layer, thickness of 1 ƒÊm, n=1 ˜10¹⁸ cm⁻³), an n-type clad layer 303 (for example, an n-type Al_{0.5}Ga_{0.5}As layer, thickness of 2.2 ƒÊm, n=7 ˜10¹⁷ cm⁻³), an n-side optical confinement layer 304 (for example, an Al_{0.3}Ga_{0.7}As layer, thickness of 10 nm), the multi-quantum well active layer 305 made by an AlGaAs well and an AlGaAs barrier, a p-side optical confinement layer 306 (for example, an Al_{0.3}Ga_{0.7}As layer, thickness of 10 nm), a p-type clad layer 307 (for example, a p-type Al_{0.5}Ga_{0.5}As layer, thickness of 1.8 ƒÊm, p=7 ˜10¹⁷ cm⁻³), and a p-type contact layer 308 (for example, a p-type GaAs layer, thickness of 400 nm, and p=5 ˜10¹⁸ cm⁻³) are laminated.

In the infrared laser 300, for transverse mode control, a part of the p-type contact layer 308 and the p-type clad layer 307 are removed by etching in the thickness direction, thereby forming a ridge 321. Further, the ridge 321 is buried with an n-type AlGaAs current block layer 309 (for example, thickness of 1 ƒÊm, n=7 ˜10¹⁷ cm⁻³) and an n-type GaAs current block layer 310 (for example, thickness of 800 nm, n=1 ˜10¹⁸ cm⁻³). On the p-type contact layer 308, a p-side electrode 311 made of Ti/Pt/Au in this order from the contact layer side is formed. On the n-type GaAs substrate 301, an n-side electrode 312 constructed by AuGe/Ni/Au is formed. The infrared laser 300 is fusion-bonded onto the blue-violet laser 100 with the p-side down via the fusion material 113 made of Au and Sn in a manner similar to the red laser 200.

Next, a method of manufacturing the three-wavelength semiconductor laser 2 will be described. The blue-violet laser 100 and the red laser 200 can be obtained by using the method described in the first embodiment.

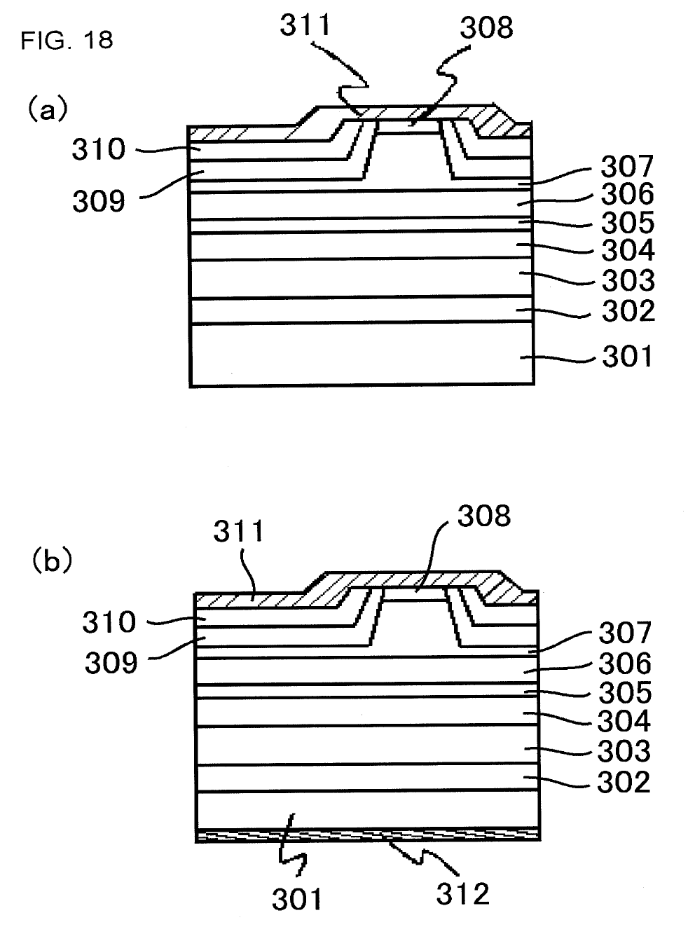

The infrared laser 300 is obtained by, for example, the following procedure. FIGS. 17(a) to 17(c) and FIGS. 18(a) and 18(b) are cross-sectional views showing the method of manufacturing the infrared laser 300.

First, on the n-type GaAs substrate 301, the n-type buffer layer 302, n-type clad layer 303, n-side optical confinement layer 304, multi-quantum well active layer 305, p-side optical confinement layer 306, p-type clad layer 307, and p-type contact layer 308 are sequentially grown (FIG. 17(a)).

For the crystal growth, for example, the MOVPE method is used. As the material, for example, TMAl, TMGa, TEGa, and AsH₃ are used. As n-type and p-type dopants, for example, Si and Zn are used, respectively. As the materials, for example, Si₂H₆ and dimethylzinc (DMZn) are used. As a carrier gas, for example, hydrogen is used. Subsequently, the ridge 321 is formed. First, a silicon oxide film 313 is deposited on the p-type contact layer 308. By selectively removing a predetermined area in the silicon oxide film 313 using photolithography, the silicon oxide film 313 is processed in a stripe shape having a width of 1.5 ƒÊm. Using the silicon oxide film 313 as a mask, dry etching is performed to etch the p-type contact layer 308 to some midpoint in the p-type clad layer 307, thereby forming the ridge 321 (FIG. 17(b)).

By, for example, selective MOVPE method, the n-type AlGaAs current block layer 309 and the n-type GaAs current block layer 310 are formed to bury the ridge 321 (FIG. 17(c)).

Subsequently, the p-side electrode 311 is formed. First, the stripe-shaped silicon oxide film 313 is removed to expose the p-type contact layer 308. On the surface of the p-type contact layer 308, the p-side electrode 311 is deposited (FIG. 18(a)). To facilitate cleavage, the n-type GaAs substrate 301 is polished to reduce the thickness to, for example, about 120 ƒÊm. The polished face is lightly etched and, after that, the n-side electrode 312 is formed on the polished face (FIG. 18(b)).

Next, for facet coating, cleavage is performed so that the cavity length becomes 900 ƒÊm. A low-reflection coating having reflectance of 5% is applied to the front facet 324, and a high-reflection coating having reflectance of 95% is applied to the rear facet 323. Finally, cleavage is performed to divide the wafer in which the plurality of ridges 321 are arranged parallel with each other like bars, into a plurality of chips. By the above-described procedure, the infrared laser 300 is obtained.

The infrared laser 300 and the red laser 200 obtained in such a manner are fusion-bonded with the p-side down to the p side of the blue-violet laser 100 shown in FIG. 16 by using the fusion material 113. As a result, the three-wavelength semiconductor laser 2 shown in FIGS. 14 and 15 is obtained.

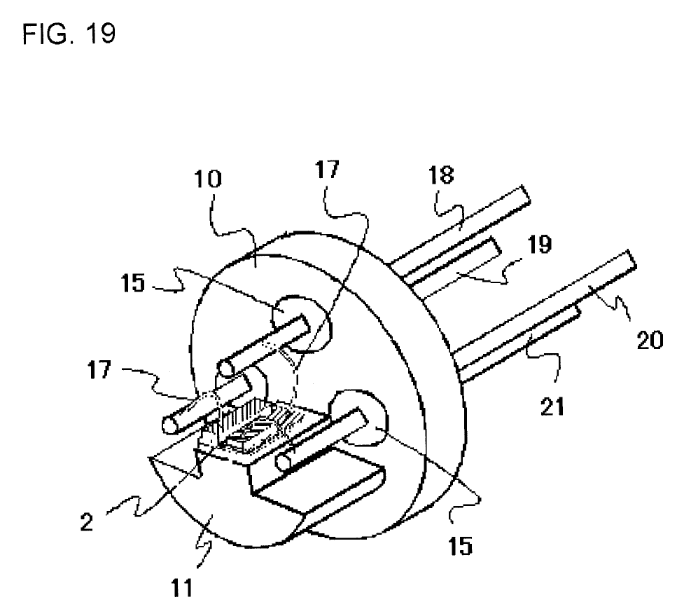

A package including the three-wavelength semiconductor laser 2 will now be described. FIG. 19 is a bird's-eye view showing a state where the three-wavelength semiconductor laser 2 is assembled in a package having a diameter of 5.6 mm.

The material of the body 10 of the package is, for example, iron. The material of a supporting member 11 and feedthroughs 18, 19, 20, and 21 is, for example, copper. The surface of each of the body 10, the supporting member 11, and the feedthroughs 18, 19, 20, and 21 is coated with gold.

Each of the feedthroughs 18, 19, and 20 is attached to the body 10 via an insulator 15 made of ceramics or the like. In such a manner, the feedthroughs and the body 10 are reliably insulated from each other.

The feedthrough 21 is connected to the body 10 and is electrically connected to the supporting member 11.

The face of the n-side electrode 112 of the blue-violet laser 100 in the three-wavelength semiconductor laser 2 is fusion-bonded to the supporting member 11 via a fusion material. Examples of the fusion material are gold tin and lead tin having a low melting point.

Further, the feedthrough 18 and the p-side electrode 111 of the blue-violet laser 100 are bonded to each other via a gold wire 17. The feedthrough 19 and the n-side electrode 211 of the red laser 200 are bonded to each other via the gold wire 17. The feedthrough 20 and the n-side electrode 312 of the infrared laser 300 are bonded to each other via the gold wire 17.

In the three-wavelength semiconductor laser 2 of the present embodiment, when a positive voltage is applied to the feedthrough 18 and a negative voltage is applied to the feedthrough 21, the blue-violet laser 100 performs laser oscillation. When a positive voltage is applied to the feedthrough 18 and a negative voltage is applied to the feedthrough 19, the red laser 200 performs laser oscillation. When a positive voltage is applied to the feedthrough 18 and a negative voltage is applied to the feedthrough 20, the infrared laser 300 performs laser oscillation.

In the three-wavelength semiconductor laser 2, the red laser 200 and the infrared laser 300 are fabricated as single elements and integrated on the blue-violet laser 100. Consequently, the elements each having the optimum cavity length adapted to a target light output power can be independently integrated.

In the three-wavelength semiconductor laser 2, the length in the cavity length direction of the n-type GaN-based substrate 101 of the GaN-based blue-violet laser 100 is equal to or longer than that of the n-type GaAs substrate 201 on which the AlGaInP-based red laser 200 which is integrated on the n-type GaN substrate 101 is provided and that of the infrared laser 300 on which the AlGaAs-based infrared laser 300 is provided. Consequently, the radiation performance of the red laser 200 and the infrared laser 300 integrated on the n-type GaN substrate 101 is improved, and a high output power characteristic equivalent to that of each of the red laser 200 and the infrared laser 300 can be realized.

In the GaN-based blue-violet laser 100, the rear facet 123 is formed by dry etching or the like. The cavity length necessary for laser oscillation is shorter than the length of the n-type GaN substrate 101 and the cavity length of each of the red laser 200 and the infrared laser 300. As a result, a waveguide loss can be reduced. In addition, the number of dislocations propagating from the n-type GaN substrate 101 to the waveguide stripe can be reduced. Therefore, laser oscillation with high-efficiency, low-drive current, and high reliability can be realized.

In the present embodiment, the case of the three-wavelength laser on which the GaN-based blue-violet laser 100, the AlGaInP-based red laser 200, and the AlGaAs-based infrared laser 300 are integrated has been described as an example. A combination of integrating a plurality of semiconductor lasers having the same wavelength is also possible. A specific example of such a configuration is a structure of integrating a write-only AlGaInP-based high-output power red laser having a long cavity length and a read-only AlGaInP-based low-output power laser having a short cavity length on the GaN-based blue-violet laser 100.

### Eighth Embodiment

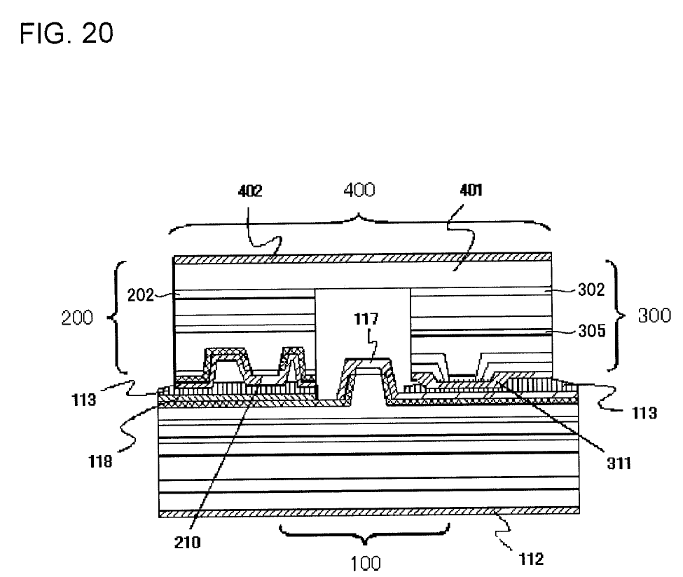

FIG. 20 is a cross-sectional view showing a configuration of a three-wavelength semiconductor laser of the present embodiment. The three-wavelength semiconductor laser shown in FIG. 20 includes the multi-quantum well active layer 305 provided in one of the faces of an n-type GaAs substrate 401, and the infrared laser 300 having the cavity length of L3. The red laser 200 and the infrared laser 300 are provided on the same side of the n-type GaAs substrate 201.

The basic configuration of the three-wavelength semiconductor laser is similar to that of the three-wavelength semiconductor laser 2 in the seventh embodiment. On the chip of the GaN-based blue-violet laser 100, the AlGaInP-based red laser 200 and the AlGaAs-based infrared laser 300 are fusion-bonded with their p sides down via the fusion material 113. The point different from the seventh embodiment is that a monolithic two-wavelength laser 400 in which the AlGaInP-based red laser 200 and the AlGaAs-based infrared laser 300 are fabricated on the single n-type GaAs substrate 401 is used.

In the three-wavelength semiconductor laser of the present embodiment, by using the monolithic two-wavelength laser 400, performing only one fusion bonding between the lasers is sufficient. That is, there is an advantage that the interval of the light emission points of three wavelengths can be determined by a single control of the light emission point interval. The reason is that, in the monolithic two-wavelength laser, the light emission point interval is easily determined by the fabricating process.

In the case of using the monolithic two-wavelength semiconductor laser, the n-type GaAs substrate 401 to which a positive voltage is applied is commonly used. To drive the red laser 200 and the infrared laser 300 separately, it is necessary to electrically separate the p-side electrodes. In the blue-violet laser 100 of the present embodiment, therefore, the p-side electrode 111 in FIG. 2 is separated to a p-side electrode 117 and two p-side electrodes 118. The other structure of the blue-violet laser 100 is similar to that of the blue-violet laser (FIGS. 14 to 16) described in the seventh embodiment.

In the three-wavelength semiconductor laser shown in FIG. 20, when a positive voltage is applied to the p-side electrode 117 and a negative voltage is applied to the n-side electrode 112, the blue-violet laser 100 performs laser oscillation. When a positive voltage is applied to the p-side electrode 210 and a negative voltage is applied to the n-side electrode 402, the red laser 200 performs laser oscillation. When a positive voltage is applied to the p-side electrode 311 and a negative voltage is applied to the n-side electrode 402, the infrared laser 300 performs laser oscillation.

The embodiments of the present invention have been described above with reference to the drawings. They are examples of the present invention and various configuration other than the above may be also employed.

For example, although an n-type substrate is used as a substrate of each of the semiconductor lasers in the foregoing embodiments, a substrate of the different conduction type or a high-resistance substrate may be used. In this case, a structure in which the polarities are reversed and a surface electrode structure may be properly employed. Also, instead of the n-type GaN substrate 101, a semiconductor substrate of another group-III nitride such as an AlGaN substrate may be used. In the first to sixth embodiments, the case of the two-wavelength semiconductor laser in which the AlGaInP-based red laser is integrated on the GaN-based blue-violet laser chip has been described as an example. A two-wavelength semiconductor laser in which the AlGaAs-based infrared laser or a laser of another wavelength band is integrated in place of the red laser may be also employed.

In the seventh and eighth embodiments, the three-wavelength semiconductor laser in which the AlGaInP-based red laser and the AlGaAs-based infrared laser are integrated on the GaN-based blue-violet laser chip has been described as an example. It is also possible to integrate a ZnMgSSe-based green-blue laser or a laser having a long wavelength range fabricated on an InP substrate. Thus, by integrating lasers of various wavelengths, various multi-wavelength semiconductor lasers may be obtained.

1. A semiconductor light emitting element including at least two laser structures that emit laser beams having wavelengths different from each other, comprising:
a first substrate;
a second substrate disposed on a predetermined face of said first substrate;
a first laser structure provided on one of faces of said first substrate and including a first active layer; and
a second laser structure provided on one of faces of said second substrate and including a second active layer,
wherein the first and second laser structures are disposed so that their cavity length directions are almost parallel with each other, and the cavity length of said first laser structure is shorter than that of said second laser structure.

2. The semiconductor light emitting element as set forth in claim 1,
wherein when the cavity length of said first laser structure is L1, the cavity length of said second laser structure is L2, and length in the cavity length direction of said first substrate is L0,
L1<L2 is satisfied and
L0 is equal to or larger than L2.

3. The semiconductor light emitting element as set forth in claim 1,
wherein a front facet or a rear facet of said first laser structure is retreated to the inner side of said first substrate compared to the facet of said first substrate.

4. The semiconductor light emitting element as set forth in claim 3,
wherein by removing a part of said first active layer by etching, the front facet or the rear facet of said first laser structure is formed retreated to the inner side of said first substrate.

5. The semiconductor light emitting element as set forth in claim 1,
Wherein said first laser structure is a GaN-based laser, and
said second laser structure is an AlGaInP-based, AlGaAs-based, GaInAs-based, AlGaInAs-based, InGaAsP-based, InGaAsN-based, or InGaAsNSb-based laser.

6. The semiconductor light emitting element as set forth in claim 5,
wherein said first laser structure is a GaN-based laser including a ridge-shaped upper clad.

7. The semiconductor light emitting element as set forth in claim 1,
wherein said first substrate is a substrate of a group-III nitride semiconductor.

8. The semiconductor light emitting element as set forth in claim 1,
wherein both of the front facet of said first laser structure and the front facet of said second laser structure are flush with the same facet of said first substrate.
